(19) United States
(12) Patent Application Publication
(10) Pub. No.: US 2022/0332133 A1
(43) Pub. Date: Oct. 20, 2022

(54) INKJET PRINTER FOR MANUFACTURING DISPLAY

(71) Applicant: STI CO., LTD., Anseong-si (KR)

(72) Inventor: Yuhho CHO, Anseong-si (KR)

(73) Assignee: STI CO., LTD., Anseong-si (KR)

(21) Appl. No.: 17/677,327

(22) Filed: Feb. 22, 2022

(30) Foreign Application Priority Data
Apr. 19, 2021 (KR) 10-2021-0050637

(51) Int. Cl. B41J 25/00; B41J 3/28

(52) U.S. Cl. CPC B41J 25/001; B41J 3/28

(57) ABSTRACT

The present invention includes a plurality of substrate stages which are provided under a head unit, on which substrates are loaded, and which move along a rail, a head unit is controlled to perform first printing on a substrate at a first position, and after the substrate stage moves, perform second printing on the one substrate at the first position or a second position, and thus a total tact time can be decreased and productivity can be improved.

### CROSS-REFERENCE TO RELATED APPLICATION

This application claims priority to and the benefit of Korean Patent Application No. 10-2021-0050637, filed on Apr. 19, 2021, the disclosure of which is incorporated herein by reference in its entirety.

### BACKGROUND

### 1. Field of the Invention

The present invention relates to a printer for manufacturing a display, and more particularly, to an inkjet printer technology allowing multi printing to be performed using one head unit for manufacturing a display.

### 2. Discussion of Related Art

Technologies of discharging color inks or resins onto substrates in an inkjet manner are applied in order to manufacture displays. Inkjet printing is non-contact patterning technology in which droplets having a size of several tens of p.m are discharged to manufacture a pattern, and since ink consumption of the inkjet printing is low, and the number of processes thereof can be greatly decreased unlike other printing technology, inkjet printing is widely used for an organic light-emitting diode (OLED) display process.

The reason why the resin is printed on the substrate is to bond a display module to a cover window or to protect the display module by sealing.

Recently, since displays have diversified, when a resin is printed on a substrate, printing is performed several times to form a specific shape. In order to form such a specific shape, a head unit for first printing and a head unit for second printing are provided on one printer to perform multi printing.

However, when one printer includes two or more head units to perform multi printing, there is a problem in that a time from loading to unloading of a substrate, that is, a tact time, increases. This is because a loaded substrate should wait until second printing is started on another substrate which was loaded before it and on which first printing is being performed. Accordingly, since a total tact time may increase and reduce productivity, increasing the productivity by solving an increase in tact time remains as a technical objective. The tact time may be a time interval between a time at which one substrate is loaded into an apparatus and a time at which another substrate is loaded into the apparatus.

In addition, even when the waiting time decreases, since there may be a case in which a stabilization time is required due to specialty of droplets, a printer which efficiently operates is required.

In a Korean patent publication (Registration Publication No. 10-2117068, “INKJET PRINTING APPARATUS AND METHOD OF INKJET PRINTING”), a technology in which two or more head units and a curing unit are provided on an inkjet printing apparatus to freely form a layer having a desired thickness on a substrate is disclosed. However, a technology of performing first printing and second printing, which is different from the first printing, and decreasing a tact time using one head unit is not disclosed.

### SUMMARY OF THE INVENTION

The present invention is directed to providing an inkjet printer technology allowing multi printing to be performed using one head unit and a total tact time to be decreased.

According to an aspect of the present invention, there is provided an inkjet printer for manufacturing a display, including a table, a gantry provided on the table and including a first rail, a head unit which is supported by the gantry, moves between a first position and a second position along the first rail, and discharges droplets to perform printing at the first position and the second position, a second rail provided on the table, a plurality of substrate stages which are provided under the head unit, on which substrates are loaded, and which move along the second rail, and a control unit which controls movement and discharge of the head unit and movement of the substrate stage, wherein the control unit controls the head unit to perform first printing on one substrate at the first position, and after the substrate stage moves, perform second printing on the one substrate at the first position or the second position.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 is a view for describing an inkjet printer according to one embodiment;

FIG. 2 is a view for describing a control operation of the inkjet printer of FIG. 1;

FIG. 3 is a view for describing a control operation of an inkjet printer divided into working zones;

FIG. 4 is a view for describing an inkjet printer (1000) according to another embodiment;

FIG. 5 is a view for describing a control operation of the inkjet printer of FIG. 4; and

FIG. 6 is a view for describing a control operation of another inkjet printer divided into working zones.

### DETAILED DESCRIPTION OF EXEMPLARY EMBODIMENTS

Hereinafter, in order to facilitate understanding and implementing the present invention through exemplary embodiments described with reference to the accompanying drawings by those skilled in the art, the present invention will be described in detail. In the description of the invention, when it is determined that detailed descriptions of related well-known components and functions unnecessarily obscure the gist of the invention, the detailed descriptions thereof will be omitted. Since the terms used herein are defined in consideration of functions in the embodiments of the present invention and may vary according to a user or operator's intentions or customs, the definitions of the terms should be interpreted based on content throughout this specification.

In addition, the above-described aspects and additional aspects of the invention will be made clear through the embodiments described below. Although the configurations of selectively described aspects or selectively described embodiments in the present specification are illustrated as a single integrated configuration in the drawings, unless otherwise described, it should be understood that these may be freely combined with each other as long as there is no clear technological contradiction in such combinations for those skilled in the art.

Therefore, since the embodiments described in this specification and configurations illustrated in the drawings are only exemplary embodiments and do not represent the overall technological scope of the invention, it should be understood that the invention covers various equivalents and modifications that can substitute for the embodiments and drawings herein at the time of filing of this application.

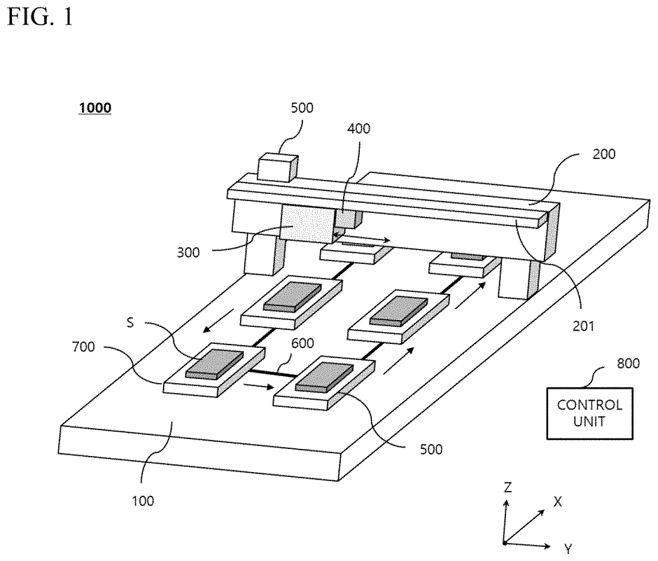

FIG. 1 is a view for describing an inkjet printer 1000 according to one embodiment. As illustrated in the drawing, the inkjet printer 1000 may include a table 100, a gantry 200, a head unit 300, an ultraviolet (UV) curing unit 400, a liquid supply unit 500, a second rail 600, a substrate stage 700, and a control unit 800.

The table 100 may be formed as a plate having a plate shape.

The gantry 200 may be provided on the table 100 and may include a first rail 201.

The head unit 300 may be supported by the gantry and may move along the first rail 201 and discharge droplets onto a substrate S. The droplets may have a resin component but are not limited thereto. The head unit 300 may be provided as a plurality of heads (not shown), and the head includes a plurality of nozzles (not shown). The UV curing unit 400 serves to cure a printed substrate and may be positioned adjacent to the heads as illustrated in the drawing.

The second rail 600 may be provided on the table 100.

The substrate stage 700 may be provided as a plurality of substrate stages 700 under the head unit 300, the substrate may be loaded on the substrate stages 700, and the substrate stages 700 may move along the second rail. The second rail may serve as a track so that the substrate stages 700 may move in a predetermined direction.

The control unit 800 may control movement and droplet discharge of the head unit 300 and movement of the substrate stage 700. The control unit 800 may be mounted on the table 100 or the gantry 200 and may also be provided in a separate space. For example, the control unit 800 may also be formed as a personal computer (PC).

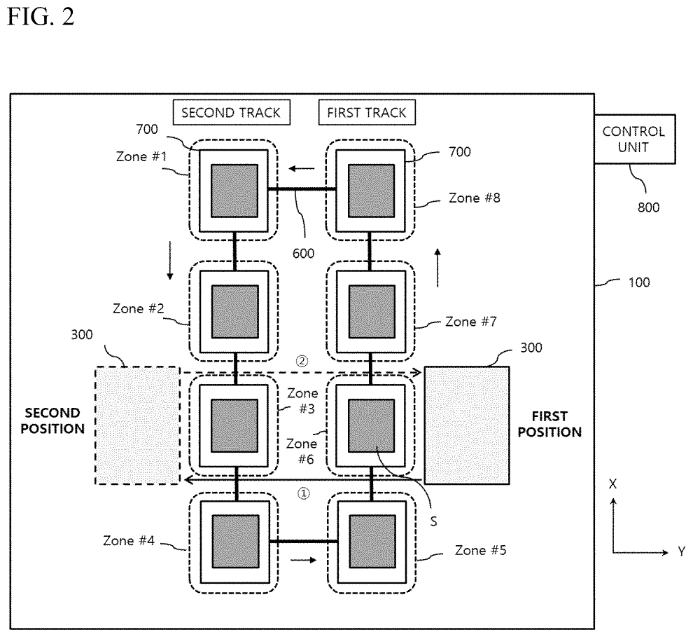

FIG. 2 is a view for describing a control operation of the inkjet printer of FIG. 1. As illustrated in the drawing, eight substrate stages 700 may move along the second rail 600 provided on the table 100. The second rail 600 may provide a first track and a second track which is adjacent and parallel to the first track. In FIG. 2, Zone #5 to Zone #8 are disposed in the first track, and Zone #1 to Zone #4 are disposed in the second track. The number of the substrate stages 700 may be flexibly set by those skilled in the art. Accordingly, ten substrate stages may be set, and in this case, ten zones are present.

According to one embodiment, the second rail may have a loop shape, and the substrate stage may rotationally move along the second rail.

The head unit 300 may discharge the droplets to perform printing at a first position and a second position while moving between the first position and the second position along the first rail. The first position is positioned on the first track, and the second position is positioned on the second track. Accordingly, the head unit 300 may reciprocate and transitionally move between the first track and the second track in a Y-axis direction. A UV curing unit may be further included in and integrated with the head unit 300.

The control unit 800 may control movement and discharge of the head unit 300 and movement of the substrate stages 700. The plurality of substrate stages 700 may each stop at corresponding zones for a temporary time while being sequentially moved by the control unit from Zone #1 to Zone #8. For example, a time taken for the substrate stage 700 to move to an adjacent zone may be set to 0.8 seconds, and printing may be set to be performed for 12.8 seconds. That is, for 12.8 seconds for which the substrates each stop at Zone #3 and Zone #6, a printing operation may be performed. In this case, the term “stop” may mean that the substrate does not depart from the corresponding zone and may include the substrate slightly moving along an X-axis in the corresponding zone for printing.

According to one embodiment, the control unit 800 may control the head unit 300 to perform first printing on one substrate at the first position, and after the substrate stage moves, perform second printing on the one substrate at the first position or the second position.

According to one embodiment, when the head unit 300 is positioned at the first position, first printing may be performed on a specific substrate S positioned in Zone #6, and when the substrate S is moved by the substrate stage 700 and positioned in Zone #3, the head unit 300 may be moved to the second position (in a direction of a solid line of \textcircled{1}) to perform second printing. In the printing, the head unit discharges droplets while moving along the first rail little by little.

In addition, when the substrate S is moved by the substrate stage 700 and positioned in Zone #6 again, the head unit 300 may also move to the first position (in a direction of a dotted line of \textcircled{2}) to perform second printing.

The first position and the second position may each be positions of the head unit at which the printing operation is performed.

A discharge position and a discharge amount of the second printing may be different from those of the first printing. For example, in the second printing, a larger amount of droplets may be discharged in an edge region or a central region of the substrate, and in the case of a foldable substrate, a larger amount of droplets may also be discharged in a region excluding a folding region.

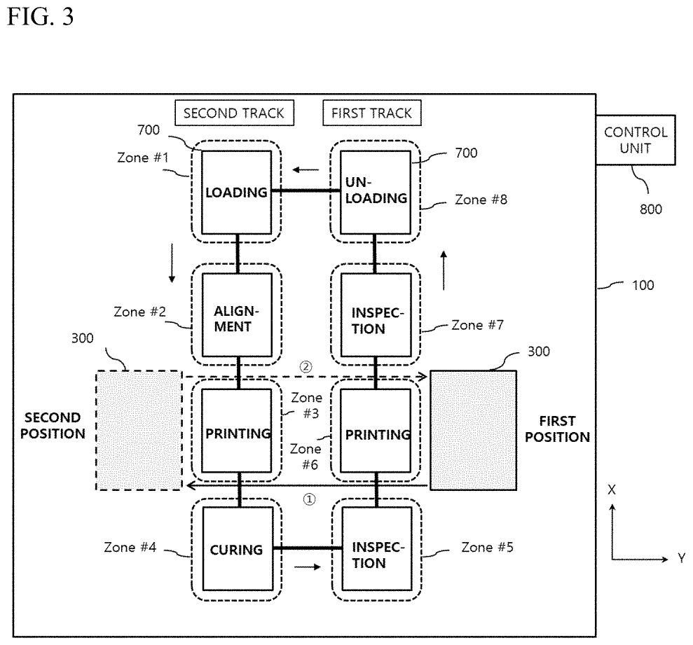

FIG. 3 is a view for describing a control operation of an inkjet printer divided into working zones. According to one embodiment, a table 100 may include a plurality of predetermined working zones, and a control unit may control a plurality of substrate stages to move to the working zones and stop at the working zones. Each zone may be a working zone.

As illustrated in the drawing, the table 100 may have the plurality of predetermined working zones. In each of Zone #1 to Zone #8, a designated working zone may be formed.

For example, Zone #1 and Zone #8 are zones in which a substrate is loaded and unloaded, Zone #2 is a zone in which the substrate is aligned, Zone #3 and Zone #6 are zones in which printing is performed on the substrate, Zone #4 is a zone in which droplets discharged onto the substrate are cured, and Zone #5 and Zone #7 may be zones in which a printing state of the substrate is inspected. When it is determined that printing is insufficient, the substrate may move to Zone #3 or Zone #6, third printing may be performed thereon, and furthermore, Nth printing may also be performed thereon. In the working zones, separate apparatuses (not shown) for performing corresponding tasks may be provided.

While a head unit moves to a first position or second position, all of the substrate stages move to the adjacent working zones, and when the head unit completely moves to the first position or the second position, the substrate stages may stop moving.

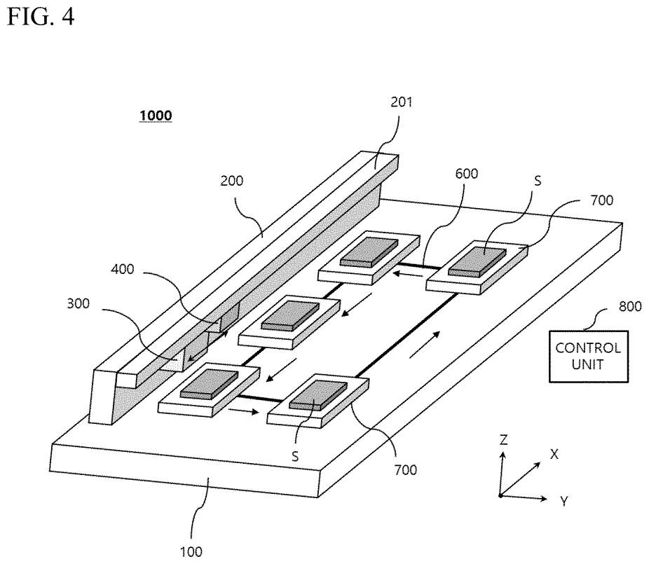

FIG. 4 is a view for describing an inkjet printer 1000 according to another embodiment. As illustrated in the drawing, the inkjet printer 1000 may include a table 100, a gantry 200, a head unit 300, a UV curing unit 400, a liquid supply unit 500, a second rail 600, a substrate stage 700, and a control unit 800.

The table 100 may be formed as a plate having a plate shape.

The gantry 200 may be provided on the table 100 and may include a first rail 201.

The head unit 300 may be supported by the gantry moved along the first rail 201 and may discharge droplets on a substrate S. The droplets may have a resin component but are not limited thereto. The head unit 300 may include a plurality of heads (not shown), and the head includes a plurality of nozzles (not shown). The UV curing unit 400 serves to cure a printed substrate and may be positioned adjacent to the heads as illustrated in the drawing.

The second rail 600 may be provided on the table 100.

The substrate stage 700 may be provided as a plurality of substrate stages 700 under the head unit 300, a substrate may be loaded on the substrate stages 700, and the substrate stages 700 may move along the second rail. The second rail may serve as a track so that the substrate stages 700 may move in a predetermined direction.

The control unit 800 may control movement and droplet discharge of the head unit 300 and movement of the substrate stage 700. The control unit 800 may be mounted on the table 100 or the gantry 200 and may also be provided in a separate space. For example, the control unit 800 may also be formed as a PC.

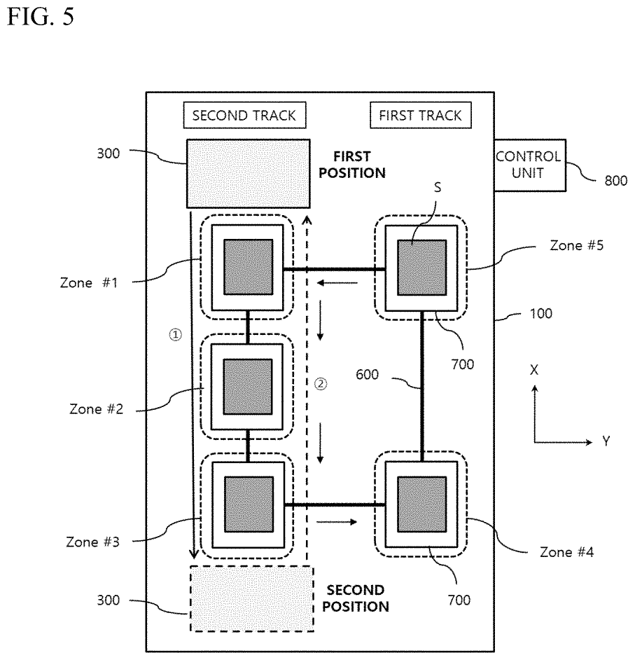

FIG. 5 is a view for describing a control operation of the inkjet printer of FIG. 4. As illustrated in the drawing, five substrate stages 700 may move along the second rail 600 provided on the table 100. The second rail 600 may provide a first track and a second track which is adjacent and parallel to the first track. In FIG. 5, Zone #4 and Zone #5 are disposed on the first track, and Zone #1 to Zone #3 are disposed on the second track.

According to one embodiment, the number of substrate stages 700 disposed on the second track may be four or more. As the number thereof increases, a time to wait for second printing after first printing increases.

According to one embodiment, the second rail may include the first track disposed so that the substrate stage transitionally moves and the second track disposed to be adjacent and parallel to the first track and having more working zones than the first track, and the head unit may transitionally move only on the first track.

According to one embodiment, the second rail may have a loop shape, and the substrate stage may rotate along the second rail.

The head unit 300 may discharge droplets at a first position and a second position to perform printing while moving between the first position and the second position along the first rail. The first position and the second position are positioned on the second track.

Accordingly, the head unit 300 may reciprocate and transitionally move along the second track in an X-axis direction. A UV curing unit may be further included in and integrated with the head unit 300.

The first position and the second position may each be positions of the head unit at which a printing operation is performed.

The control unit 800 may control movement and discharge of the head unit 300 and movement of the substrate stage 700. The plurality of substrate stages 700 may each stop at corresponding zones for a temporary time while being sequentially moved by the control unit from Zone #1 to Zone #5. For example, a time taken for the substrate stage 700 to move to an adjacent zone may be set to 0.6 seconds, and printing may be set to be performed for 12.3 seconds. That is, for 12.3 seconds for which the substrates stop at Zone #3 and Zone #6, a printing operation may be performed. In this case, the term “stop” may mean that the substrate does not depart from the corresponding zone and may include the substrate slightly moving along the X-axis in the corresponding zone for printing.

According to one embodiment, the control unit 800 may control the head unit 300 to perform first printing on one substrate at the first position, and after the substrate stage moves, perform second printing on the one substrate at the first position or the second position.

For example, when the head unit 300 is positioned at the first position, first printing may be performed on a specific substrate S positioned in Zone #1, and when the substrate S is moved by the substrate stage 700 and positioned in Zone #3, the head unit 300 may be moved to the second position (in a direction of a solid line of \textcircled{1} ) to perform second printing. In addition, the head unit 300 may move to the first position again (in a direction of a dotted line of \textcircled{2}) to perform first printing on another substrate. In the printing, the head unit discharges droplets while moving along the first rail little by little.

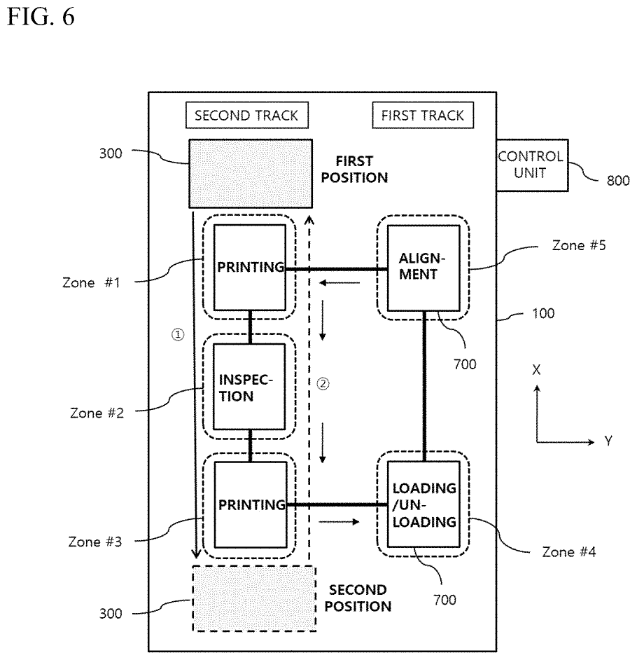

FIG. 6 is a view for describing a control operation of another inkjet printer divided into working zones. According to one embodiment, a table 100 may include a plurality of predetermined working zones, and a control unit may control substrate stages to move to the working zones and stop at the working zones. Each zone may be a working zone.

In each of Zone #1 to Zone #5, a designated working zone may be formed.

For example, Zone #4 is a zone in which a substrate is loaded and unloaded, Zone #5 is a zone in which the substrate is aligned, Zone #1 and Zone #3 are zones in which printing is performed on the substrate, and Zone #2 is a zone in which a first printing result is inspected. When it is determined that printing is insufficient, the printing may be corrected in the second printing, and furthermore, third or later printing may also be performed.

In the working zones, separate apparatuses (not shown) for performing corresponding tasks may be provided.

While a head unit moves to a first position or second position, all of the substrate stages move to the adjacent working zones, and when the head unit completely moves to the first position or the second position, the substrate stages may stop moving.

According to embodiments, since multi printing can be performed using one head unit, a total tact time can be decreased to improve productivity.

In addition, since the number of head units can decrease, manufacturing costs of an inkjet printer can be reduced.

In addition, since a plurality of substrate stages can be provided, a large number of substrates can be processed to improve productivity.

In addition, since a substrate stage of a zone in which a printing process is not performed does not simply standby but performs another process, a stabilization time is secured sufficiently, and thus a total tact time can be reduced to improve productivity.

What is claimed is:

1. An inkjet printer for manufacturing a display, comprising:
a table;
a gantry provided on the table and including a first rail;
a head unit which is supported by the gantry, moves between a first position and a second position along the first rail, and discharges droplets to perform printing at the first position and the second position;
a second rail provided on the table;
a plurality of substrate stages which are provided under the head unit, on which substrates are loaded, and which move along the second rail; and
a control unit which controls movement and discharge of the head unit and movement of the substrate stage,
wherein the control unit controls the head unit to perform first printing on one substrate at the first position, and after the substrate stage moves, perform second printing on the one substrate at the first position or the second position.

2. The inkjet printer of claim 1, wherein:
the second rail has a loop shape; and
the substrate stage rotationally moves along the second rail.

3. The inkjet printer of claim 1, wherein:
the table includes a plurality of predetermined working zones; and
the control unit controls the substrate stage to move to the working zones and stop at the working zones.

4. The inkjet printer of claim 3, wherein:
the second rail include a first track disposed so that the substrate stage transitionally moves; and
a second track which is disposed parallel and adjacent to the first track and includes more working zones than the first track,
wherein the head unit transitionally moves only on the first track.
